(19) United States
(12) Patent Application Publication
(10) Pub. No.: US 2025/0167123 A1
(43) Pub. Date: May 22, 2025

(54) SEMICONDUCTOR DIE HAVING A METAL PLATE LAYER

(71) Applicant: SK hynix Inc., Icheon-si Gyeonggi-do (KR)

(72) Inventors: Jae Jun LEE, Icheon-si Gyeonggi-do (KR); Sung Kyu KIM, Icheon-si Gyeonggi-do (KR); Jong Yeon KIM, Icheon-si Gyeonggi-do (KR); Ki Ill MOON, Icheon-si Gyeonggi-do (KR); Ju Heon YANG, Icheon-si Gyeonggi-do (KR); BEOLI OK, Icheon-si Gyeonggi-do (KR)

(73) Assignee: SK hynix Inc., Icheon-si Gyeonggi-do (KR)

(21) Appl. No.: 19/035,040

(22) Filed: Jan. 23, 2025

Related U.S. Application Data
(63) Continuation-in-part of application No. 18/497,654, filed on Oct. 30, 2023.

(30) Foreign Application Priority Data
May 23, 2023 (KR) 10-2023-0066122

(51) Int. Cl. H01L 23/528; H01L 23/00; H01L 23/522; H01L 25/065

(52) U.S. Cl. CPC H01L 23/5286; H01L 23/5226; H01L 24/13; H01L 25/0652; H01L 25/0657; H01L 24/16; H01L 2224/13023; H01L 2224/13025; H01L 2224/16148; H01L 2224/16238; H01L 2225/06513; H01L 2225/06517; H01L 2225/06544; H01L 2924/3511; H01L 2924/35121

(57) ABSTRACT

A semiconductor die includes interlayer insulating layer, a signal horizontal metal interconnection and a power horizontal metal interconnection, a front-side passivation layer, a signal front-side bump structure and a power front-side bump structure, a signal vertical via plug, and a power vertical via plug over a front-side of a substrate; and a back-side insulating layer, a back-side metal plate layer, a back-side passivation layer, a signal back-side bump structure and a power back-side bump structure, a signal through-electrode, and a power through-electrode over a back-side of the substrate. Upper ends of the signal through-electrode and the power through-electrode protrude from the back-side surface of the substrate. The back-side metal plate layer is not to be electrically connected to the signal through-electrode. The back-side metal plate layer is electrically connected to the power bump structure.

### CROSS-REFERENCE TO RELATED APPLICATIONS

The present application is a continuation-in-part application of U.S. patent application Ser. No. 18/497,654 filed on Oct. 30, 2023, which claims priority under 35 U.S.C. § 119(a) to Korean Patent Application No. 10-2023-0066122, filed on May 23, 2023, the entire contents of which applications are incorporated herein by reference.

### BACKGROUND

### 1. Field

The present disclosure provides a semiconductor die having a through-electrode, a front-side bump structure, and a back-side bump structure.

### 2. Description of the Related Art

A warpage of a semiconductor die occurs during a semiconductor die manufacturing process.

### SUMMARY

An embodiment of the present disclosure provides a semiconductor die including a substrate having a front-side surface and a back-side surface; an interlayer insulating layer disposed under the front-side surface of the substrate; a horizontal metal interconnection disposed in the interlayer insulating layer; a metal pad disposed under a lower surface of the interlayer insulating layer; a front-side bump structure disposed under a lower surface of the metal pad; a through-electrode vertically passing through the substrate; a back-side insulating layer disposed over the back-side surface of the substrate; a first metal plate layer disposed over the back-side insulating layer; a back-side passivation layer disposed over the back-side insulating layer and covering the first metal plate layer; and a back-side bump structure disposed over the through-electrode and the back-side passivation layer. The through-electrode has a protruding portion that vertically passes through the back-side passivation layer and the first metal plate layer. The protruding portion protrudes upward from the back-side surface of the substrate.

An embodiment of the present disclosure provides a semiconductor device including a substrate having a through-electrode area and a dummy area; an interlayer insulating layer disposed under an active surface of the substrate; a horizontal metal interconnection disposed in the interlayer insulating layer; a front-side passivation layer disposed under a lower surface of the interlayer insulating layer; a front-side bump structure disposed under a lower surface of the front-side passivation layer in the through-electrode area; a dummy front-side bump structure disposed under the lower surface of the front-side passivation layer in the dummy area; a back-side insulating layer disposed over an in-active surface of the substrate; a first metal plate layer disposed over the back-side insulating layer; a back-side passivation layer disposed over the first metal plate layer; a through-electrode vertically passing through the substrate, the back-side insulating layer, the first metal plate layer, and the back-side passivation layer in the through-electrode area; a back-side bump structure disposed over the through-electrode in the through-electrode area; and a dummy back-side bump structure disposed over the back-side passivation layer in the dummy area.

An embodiment of the present disclosure provides a semiconductor die comprising interlayer insulating layer over a front-side of a substrate; a signal horizontal metal interconnection and a power horizontal metal interconnection in the interlayer insulating layer; a front-side passivation layer over the interlayer insulating layer; a signal front-side bump structure and a power front-side bump structure over the front-side passivation layer; a signal vertical via plug passing through the front-side passivation layer to electrically connect the signal horizontal metal interconnection to the signal front-side bump structure; a power vertical via plug passing through the front-side passivation layer to electrically connect the power horizontal metal interconnection to the power front-side bump structure; a back-side insulating layer over a back-side of the substrate; a back-side metal plate layer over the back-side insulating layer; a back-side passivation layer covering the back-side metal plate layer; a signal back-side bump structure and a power back-side bump structure over the back-side passivation layer; a signal through-electrode passing through the substrate to electrically connect the signal horizontal metal interconnection to the signal back-side bump structure; and a power through-electrode passing through the substrate to electrically connect the power horizontal metal interconnection to the power back-side bump structure. Upper ends of the signal through-electrode and the power through-electrode protrude from the back-side surface of the substrate. The back-side metal plate layer is spaced apart from the signal through-electrode so as not to be electrically connected to the signal through-electrode. The back-side metal plate layer is electrically connected to the power bump structure.

An embodiment of the present disclosure provides a semiconductor die comprising an interlayer insulating layer over a front-side of a substrate; a first horizontal metal interconnection, a second horizontal metal interconnection, and a third horizontal metal interconnection in the interlayer insulating layer; a front-side passivation layer over the interlayer insulating layer; a first front-side bump structure, a second front-side bump structure, and a third front-side bump structure over the front-side passivation layer; a first vertical via plug passing through the front-side passivation layer to electrically connect the first horizontal metal interconnection to the first front-side bump structure; a second vertical via plug passing through the front-side passivation layer to electrically connect the second horizontal metal interconnection to the second front-side bump structure; a back-side insulating layer over a back-side of the substrate; a back-side metal plate layer over the back-side insulating layer; a back-side passivation layer covering the back-side metal plate layer; a first back-side bump structure, a second back-side bump structure, and a third back-side bump structure over the back-side passivation layer; a first through-electrode passing through the substrate to electrically connect the first horizontal metal interconnection to the first back-side bump structure; and a second through-electrode passing through the substrate to electrically connect the second horizontal metal interconnection to the second back-side bump structure. The back-side metal plate layer is spaced apart from the first back-side bump structure and the first through-electrode, respectively. The back-side metal plate layer is electrically and physically connected to the second back-side bump structure. The back-side metal plate layer is vertically overlapped with the third back-side bump structure.

### BRIEF DESCRIPTION OF THE DRAWINGS

FIG. 1 is a top view illustrating a back-side surface of a semiconductor die according to an embodiment of the present disclosure.

FIGS. 2A to 2E are longitudinal cross-sectional views illustrating semiconductor dies according to embodiments of the present disclosure.

FIGS. 3A, 3B, 4A, 4B, 5A, and 5B are top views of semiconductor dies according to embodiments of the present disclosure and longitudinal cross-sectional views taken along the line I-I′ of FIG. 1.

FIG. 6 is a schematic top view of a back-side surface of a semiconductor die according to an embodiment of the present disclosure.

FIG. 7A is an enlarged top view of an area A of FIG. 6, and FIG. 7B is a longitudinal cross-sectional view taken along the line III-III′ of FIG. 7A.

FIG. 8A is an enlarged top view of an area B of FIG. 6, and FIG. 8B is a longitudinal cross-sectional view taken along the line IV-IV′ of FIG. 8A.

FIG. 9A is an enlarged top view of an area C of FIG. 6, and FIG. 9B is a longitudinal cross-sectional view taken along the line V-V′ of FIG. 9A.

FIG. 10 is a longitudinal cross-sectional view schematically illustrating a semiconductor die stack structure according to an embodiment of the present disclosure.

FIGS. 11A, 11B, 11C, 12A, 12B, 12C, 13A, 13B, 13C, 14A, 14B, 14C, 15A, 15B, 15C, 16A, 16B, 16C, 17A, 17B, 17C, 18A, 18B, and 18C are longitudinal cross-sectional views illustrating a method of manufacturing a semiconductor die according to an embodiment of the present disclosure.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

It will be understood that, although the terms “first” and/or “second” may be used herein to describe various elements, these elements should not be limited by these terms. These terms are only used to distinguish one element, from another element. For instance, a first element discussed below could be termed a second element without departing from the teachings of the present disclosure. Similarly, the second element could also be termed the first element.

Other expressions that explain the relationship between elements, such as “between”, “directly between”, “adjacent to” or “directly adjacent to” should be construed in the same way.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

An embodiment of the present disclosure provides a structure for preventing or reducing a warpage of a semiconductor die.

An embodiment of the present disclosure provides a semiconductor die having a metal plate layer.

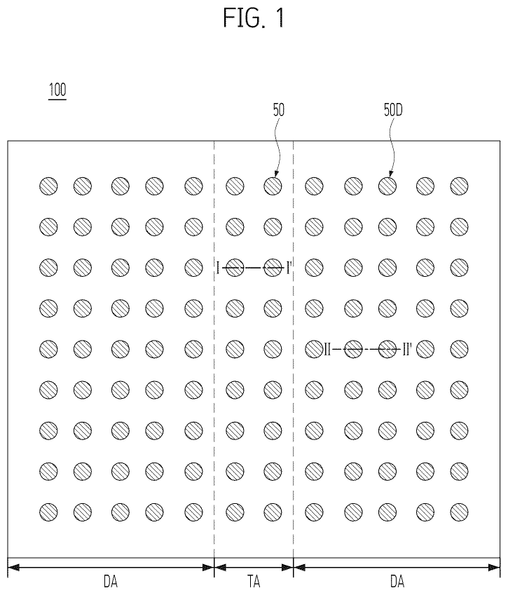

FIG. 1 is a top view illustrating a back-side surface of a semiconductor die 100 according to an embodiment of the present disclosure. Referring to FIG. 1, a semiconductor die 100 according to an embodiment of the present disclosure may include a through-electrode area TA and dummy areas DA. The through-electrode area TA may be disposed between the dummy areas DA. Back-side bump structures 50 may be disposed in the through-electrode area TA, and dummy back-side bump structures 50D may be disposed in the dummy area DA. The back-side bump structures 50 and the dummy back-side bump structures 50D may be arranged in a grid array shape.

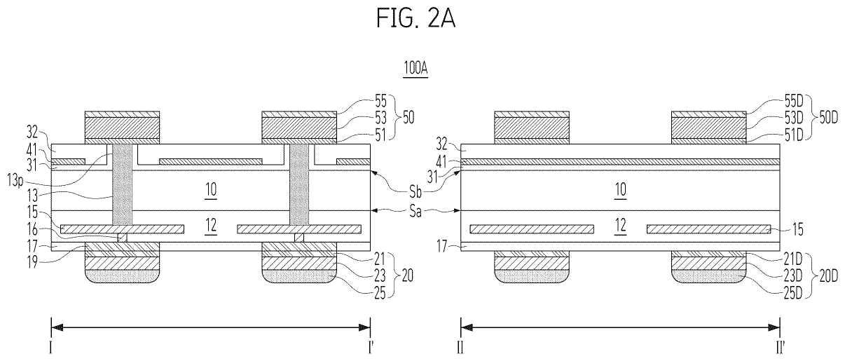

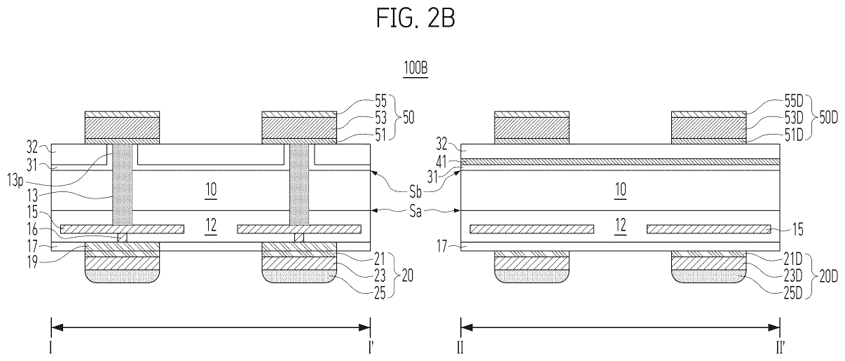

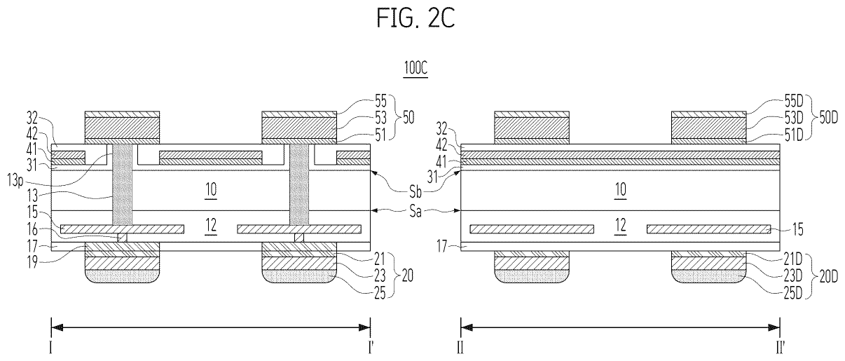

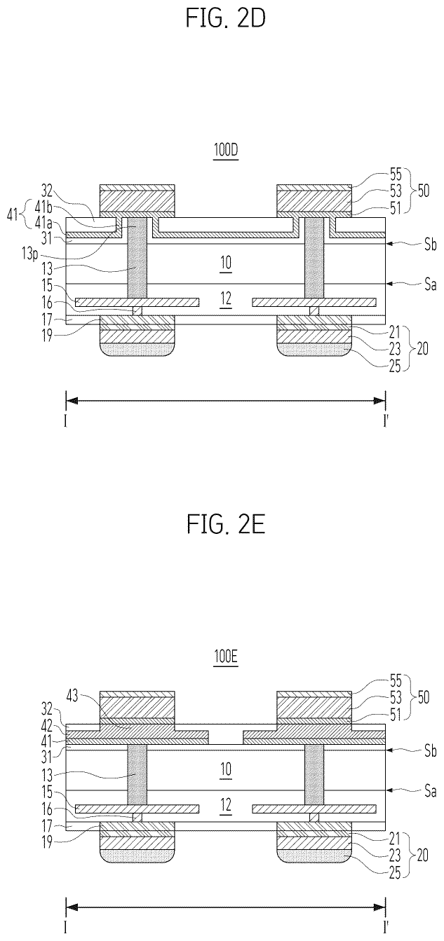

FIGS. 2A to 2E are longitudinal cross-sectional views illustrating semiconductor dies 100A-100E according to embodiments of the present disclosure. For example, FIGS. 2A to 2E are longitudinal cross-sectional views taken along the lines I-I′ and/or II-II′ of FIG. 1. Referring to FIGS. 1 and 2A, a semiconductor die 100A according to an embodiment of the present disclosure may include a substrate 10, through-electrodes 13, front-side bump structures 20, dummy front-side bump structures 20D, a first back-side metal plate layer 41, back-side bump structures 50, and dummy back-side bump structures 50D. The semiconductor die 100A may further include an interlayer insulation layer 12, horizontal metal interconnections 15, vertical via plugs 16, a front-side passivation layer 17, front-side pads 19, a back-side insulation layer 31, and a back-side passivation layer 32. The through-electrodes 13, the front-side bump structures 20, the back-side bump structures 50, the vertical via plugs 16, and the front-side pads 19 may be disposed in the through-electrode area TA. The dummy front-side bump structures 20D and the dummy back-side bump structures 50D may be disposed in the dummy areas DA. The interlayer insulating layer 12, the horizontal metal interconnections 15, the front-side passivation layer 17, the back-side passivation layer 32, and the first back-side metal plate layer 41 may be disposed in both the through-electrode area TA and the dummy area DA. In the through-electrode area TA, the through-electrodes 13, the horizontal metal interconnections 15, the vertical via plugs 16, the front-side pads 19, the front-side bump structures 20, and the back-side bump structures 50 may be electrically connected to each other. In the dummy areas DA, the horizontal metal interconnections 15, the dummy front-side bump structures 20D, and the dummy back-side bump structures 50D might not be electrically connected to each other.

The substrate 10 may include a semiconductor layer such as a silicon wafer, a silicon germanium wafer, an epitaxially grown silicon layer, an epitaxially grown silicon germanium layer, or SOI (silicon on insulator). In an embodiment, the substrate 10 may include a silicon wafer. The substrate 10 may have a front-side surface Sa and a back-side surface Sb. The front-side surface Sa may correspond to an active surface of the substrate 10, and the back-side surface Sb may correspond to an in-active surface of the substrate 10. For example, active circuit elements such as transistors may be disposed on the front-side surface Sa of the substrate 10, and any active circuit elements might not be disposed on the back-side surface Sb of the substrate 10. In the drawing, the front-side surface Sa of the substrate 10 may face downward, and the back-side surface Sb of the substrate 10 may face upward.

Electrical circuit elements such as transistors and metal interconnections may be disposed on the front-side surface Sa of the substrate 10. The interlayer insulating layer 12 may be disposed on the front-side surface Sa of the substrate 10 to cover the electrical circuit elements. The interlayer insulating layer 12 may include a silicon oxide-based insulating layer and a silicon nitride-based insulating layer.

The through-electrodes 13 may vertically pass through the substrate 10. The through-electrodes 13 may pass through a portion of the interlayer insulating layer 12. The through-electrodes 13 may include protruding portions 13p protruding upward from the back-side surface Sb of the substrate 10 to be exposed. For example, top ends of the through-electrodes 13 may protrude upward from the back-side surface of the substrate 10 to be exposed. The through-electrodes 13 may include copper.

The horizontal metal interconnections 15 may be connected to end portions of the through-electrodes 13 in the interlayer insulating layer 12. Although not shown, the horizontal metal interconnections 15 may include a plurality of metal layers extending in a horizontal direction. The horizontal metal interconnections 15 may include a metal such as copper or tungsten.

The vertical via plugs 16 may vertically pass through the interlayer insulating layer 12 and electrically connect the horizontal metal interconnections 15 to the metal pads 19 in a vertical direction, respectively. The vertical via plugs 16 may include a metal such as copper or tungsten.

The front-side passivation layer 17 may be disposed under a lower surface of the interlayer insulating layer 12 disposed under the front-side surface Sa of the substrate 10. The front-side passivation layer 17 may include an insulating material such as silicon oxide or silicon nitride. The front-side passivation layer 17 may surround side surfaces of the metal pads 19. The front-side passivation layer 17 may expose lower surfaces of the metal pads 19.

The metal pads 19 may include metal. For example, the metal pads 19 may include aluminum or tungsten. The metal pads 19 may correspond to the top metal layer among multiple metal layers of the electrical circuit elements of semiconductor devices.

The front-side bump structures 20 may be disposed under the lower surfaces of the metal pads 19 in the through-electrode area TA. In the dummy areas DA, the dummy front-side bump structures 20D may be disposed under a lower surface of the front-side passivation layer 17. The front-side bump structures 20 may be electrically connected to the through-electrodes 13, and the dummy front-side bump structures 20D might not be electrically connected to the through-electrodes 13.

Each of the front-side bump structures 20 may include a front-side UBM (Under Bump Metallurgy) layer 21, a front-side bump body 23, and a solder layer 25. Each of the dummy front-side bump structures 20D may include a dummy front-side UBM layer 21D, a dummy front-side bump body 23D, and a dummy solder layer 25D. The front-side UBM layers 21 may be disposed directly under the lower surfaces of the metal pads 19. The dummy front-side UBM layers 21D may be disposed directly under the lower surface of the front-side passivation layer 17. Each of the front-side UBM layers 21 and each of the dummy front-side UBM layers 21D may include a lower UBM layer and an upper UBM layer. The lower UBM layer may include a metal to reinforce an adhesive force to the front-side passivation layer 17 and the metal pads 19. For example, the lower UBM layer may include a titanium layer or a titanium tungsten layer. The upper UBM layer may include at least one of a copper layer and a nickel layer. The upper UBM layer may be used as a seed layer in a plating process for forming the front-side bump body 23 and the dummy front-side bump body 23D. The front-side bump body 23 and the dummy front-side bump body 23D may include a metal having excellent conductivity. For example, the bump body 23 and the dummy front-side bump body 23D may include at least one of nickel or copper. In an embodiment, the front-side bump body 23 and the dummy front-side bump body 23D may include nickel having good corrosion resistance. The solder layers 25 and the dummy solder layers 25D may include an alloy of metals such as tin (Sn) and silver (Ag).

The back-side insulating layer 31 may be conformally disposed on the back-side surface Sb of the substrate 10. Portions of the back-side insulating layer 31 may protrude upward to surround side surfaces of the protruding portions 13p of the through-electrodes 13 protruding upward from the back-side Sb of the substrate 10 to be exposed. For example, the back-side insulating layer 31 may be conformally disposed on the back-side surface Sb of the substrate 10 and on the side surfaces of the protruding portions 13p of the through-electrodes 13. The protruding portions of the back-side insulating layer 31 may have a cylinder shape or a tube shape. The back-side insulating layer 31 may include a silicon nitride-based insulating material.

The first back-side metal plate layer 41 may be disposed on the back-side insulating layer 31 in a plate shape. The first back-side metal plate layer 41 may be disposed to be horizontally spaced apart from the through-electrodes 13 in the through-electrode area TA. The first back-side metal plate layer 41 may include double layers having a lower metal layer and an upper metal layer. The lower metal layer may include a metallic adhesive layer to increase bonding strength between the upper metal layer and the back-side insulating layer 31. For example, the lower metal layer may include a titanium layer or a titanium tungsten layer. The upper metal layer may include at least one of metals such as copper or nickel. The first back-side metal plate layer 41 may be formed using a physical vapor deposition (PVD) process such as sputtering. For example, both the lower metal layer and the upper metal layer may be formed using the PVD process.

The back-side passivation layer 32 may be disposed on the back-side insulating layer 31 to cover the first back-side metal plate layer 41. The back-side passivation layer 32 may surround the protruding portions of the back-side insulating layer 31 surrounding the sides of the protruding portions 13p of the through-electrodes 13. Top end surfaces of the through-electrodes 13, top end surfaces of the back-side insulating layer 31, and top surface of the back-side passivation layer 32 may be coplanar.

Each of the back-side bump structures 50 may include a back-side UBM layer 51, a back-side bump body 53, and a back-side bump capping layer 55. Each of the dummy back-side bump structure 50D may include a dummy back-side UBM layer 51D, a dummy back-side bump body 53D, and a dummy back-side bump capping layer 55D. In the through-electrode area TA, the back-side UBM layer 51 may be disposed on the top surface of the back-side passivation layer 32, the top end surface of the back-side insulation layer 31, and the top ends of the penetrating electrodes 13. In the dummy areas DA, the dummy back-side UBM layer 51D may be disposed on the top surface of the back-side passivation layer 32. The back-side UBM layer 51 and the dummy back-side UBM layer 51D may include a lower UBM layer and an upper UBM layer, respectively. The lower UBM layer may include a metal layer such as a titanium layer or a titanium tungsten layer. The upper UBM layer may include the same metal as the bump body 53. The upper UBM layer may include at least one of copper or nickel. The upper UBM layer may be used as a seed layer in a plating process for forming the back-side bump body 53 and the dummy back-side bump body 53D. The back-side bump body 53 and the dummy back-side bump body 53D may include at least one of nickel or copper. The back-side bump capping layer 55 and the dummy back-side bump capping layer 55D may include a metal diffusion barrier layer such as nickel or an oxidation-resistive metal or a corrosion-resistive metal such as gold. The back-side bump structures 50 may be vertically aligned with and electrically connected to the through-electrodes 13, respectively. The dummy back-side bump structures 50D might not be vertically aligned with and might not be electrically connected to the through-electrodes 13.

The first back-side metal plate layer 41 may compensate for thermal expansion of metal layers and insulating material layers disposed on the front-side surface Sa of the substrate 10. Accordingly, the first back-side metal plate layer 41 can prevent, alleviate, and compensate warpage and bending of the substrate 10, the interlayer insulating layer 12, the horizontal metal wires 15, the front-side passivation layer 17, the back-side insulating layer 31, and the back-side passivation layer 32. In addition, the first back-side metal plate layer 41 may prevent and alleviate delamination between elements. Referring to FIG. 2B, a semiconductor die 100B according to

an embodiment of the present disclosure may include a substrate 10, through-electrodes 13, front-side bump structures 20, dummy front-side bump structures 20D, first back-side metal plate layer 41, back-side bump structures 50, and dummy back-side bump structures 50D. The first back-side metal plate layer 41 may be disposed only in the dummy area DA. The first back-side metal plate layer 41 might not be disposed in the through-electrode area TA. The first back-side metal plate layer 41 may be selectively disposed at selected positions. For example, when operation of the semiconductor die 100B is affected by a parasitic capacitance or an electrical interference between the first metal plate layer 41 and the through-electrodes 13, the first metal plate layer 41 may be omitted in the through-electrode area TA.

Referring to FIG. 2C, a semiconductor die 100C according to an embodiment of the present disclosure may further include a second back-side metal plate layer 42 disposed on the first back-side metal plate layer 41. In an embodiment, the second back-side metal plate layer 42 may include the same metal as the upper metal layer of the first back-side metal plate layer 41. For example, the second back-side metal plate layer 42 may include at least one of copper or nickel. The first back-side metal plate layer 41 may include a lower metal layer and an upper metal layer formed by PVD processes. The second back-side metal plate layer 42 may include a metal layer formed by a plating process.

In another embodiment, the first back-side metal plate layer 41 may be a single layer including a titanium layer or a titanium tungsten layer formed by performing the PVD process. The second back-side metal plate layer 42 may be a double layer including a lower metal layer formed by performing the PVD process and an upper metal layer formed by performing the plating process. In the embodiment, the lower metal layer and the upper metal layer of the second back-side metal plate layer 42 may include at least one of copper or nickel. For example, the lower metal layer and the upper metal layer of the second back-side metal plate layer 42 may include the same metal. The second back-side metal plate layer 42 may be twice or more thicker than the first back-side metal plate layer 41. Side surfaces of the first back-side metal plate layer 41 and side surfaces of the second back-side metal plate layer 42 may be substantially vertically aligned with each other. In an embodiment, the side surfaces of the first back-side metal plate layer 41 may be under-cut below the lower surface of the second back-side metal plate layer 42. The second back-side metal plate layer 42 may be disposed in both the through-electrode area TA and the dummy area DA. In another embodiment, the second back-side metal plate layer 42 might not be disposed in the through-electrode area TA. The second back-side metal plate layer 42 may be disposed only in the dummy areas DA.

In a viewpoint of a process for forming the first back-side metal plate layer 41, when a PVD process and an etching process are difficult to be performed, the second back-side metal plate layer 42 having a sufficient thickness may be formed using the plating process. For example, the second back-side metal plate layer 42 may be formed to be twice or thicker than the first back-side metal plate layer 41. By adding the second back-side metal plate layer 42, warpage resistance and bending resistance may be further enhanced. For example, when the first back-side metal plate layer 41 does not sufficiently prevent the warpage and bending of the substrate 10, the second back-side metal plate layer 42 which is thicker than the first back-side metal plate layer 41 can reinforce the warpage resistance and the bending resistance.

Referring to FIG. 2D, a semiconductor die 100D according to an embodiment of the present disclosure may include a first back-side metal plate layer 41 electrically connected to the back-side bump structure 50. A portion of the first back-side insulating layer 31 may protrude to conformally surround a side surface of the protruding portion 13p of the through-electrode 13. The first back-side metal plate layer 41 may include a horizontal plate portion 41a and a vertical protruding portion 41b. The horizontal plate portion 41a may have a plate shape between the back-side insulating layer 31 and the back-side passivation layer 32. The vertical protruding portion 41b may surround the side surface of the protruding portion of the back-side insulating layer 31 surrounding the side surfaces of the protruding portion 13p of the through-electrode 13. The vertical protruding portion 41b may protrude upward from the horizontal plate portion 41a to have a cylindrical shape or a tube shape. Accordingly, the first back-side metal plate layer 41 and the back-side UBM layers 51 of the back-side bump structure 50 may be physically and electrically connected to each other. When the through-electrode 13 and the back-side bump structure 50 transmit a common electrical signal, such as a common power voltage or a ground voltage, the first metal plate layer 41 may electrically connect the through-electrode 13 to the back-side bump structure 50 such as a power plane or a ground plane. Accordingly, the first metal plate layer 41 may provide a stable power supply effect, a decoupling effect, a shielding effect, and other electrical stabilization effects.

Referring to FIG. 2E, a semiconductor die 100E according to an embodiment of the present disclosure may include a substrate 10, through-electrode 13, front-side bump structure 20 and dummy front-side bump structure 20D, first and second back-side metal plate layers 41 and 42, and back-side bump structure 50 and dummy back-side bump structure 50D. The first and second metal plate layers 41 and 42 may be disposed on the through-electrode 13. The semiconductor die 100E may further include metal pattern 43 disposed on the second back-side metal plate layer 42. The metal pattern 43 may be disposed between the second back-side metal plate layer 42 and the back-side bump structure 50. The metal pattern 43 may be disposed on a portion of a top surface of the second back-side metal plate layer 42 in an upwardly protruding shape. The second back-side metal plate layer 42 and the metal pattern 43 may form a staircase. The metal pattern 43 may be vertically aligned with the through-electrode 13 and/or the back-side bump structure 50. The metal pattern 43 may include the same metal as the second back-side metal plate layer 42. Accordingly, an interface between the second back-side metal plate layer 42 and the metal pattern 43 may exist virtually. The first back-side metal plate layer 41, the second back-side metal plate layer 42, the metal pattern 43, and the back-side bump structure 50 may be electrically connected with other.

In another embodiment, the back-side UBM layer 51 may be omitted. For example, the metal pattern 43 and the back-side bump body 53 may include the same material to be materially continued with each other.

In another embodiment, the second back-side metal plate layer 42 may be omitted. For example, the metal pattern 43 may be directly disposed on the first back-side metal plate layer 41 in a mesa shape upwardly protruding. Accordingly, the metal pattern 43 may be disposed between the first back-side metal plate layer 41 and the back-side bump structure 50.

The semiconductor dies 100A-100E according to the embodiments of the present disclosure may include the back-side metal plate layers 41 and 42 and the metal pattern 43 disposed on the back-side surface Sb of the substrate 10. Accordingly, warpages caused by differences in thermal expansion rates among the multiple metal layers and the insulating layers disposed under the front-side surface Sa of the substrate 10 can be prevented, alleviated, and compensated.

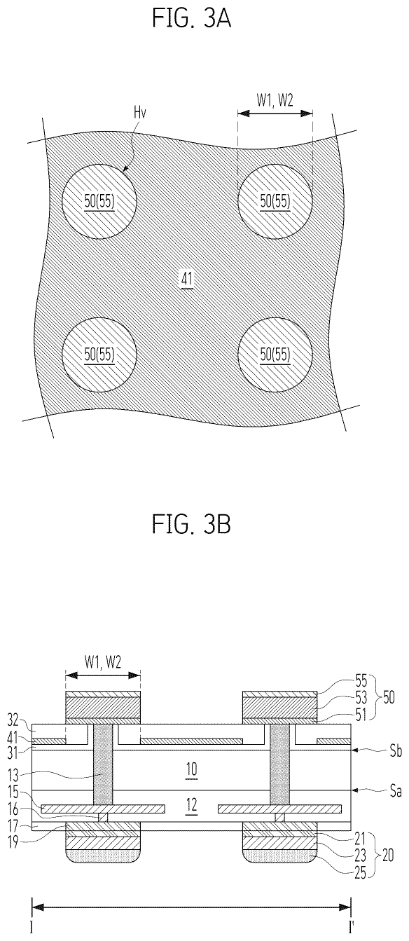

FIGS. 3A and 3B to 5A and 5B are top views of semiconductor dies according to embodiments of the present disclosure and longitudinal cross-sectional views taken along the line I-I′ of FIG. 1. Referring to FIGS. 3A and 3B, the first back-side metal plate layer 41 may include through-electrode holes Hv each having a circular shape. The first back-side metal plate layer 41 and the back-side bump structures 50 might not be vertically overlapped each other. The maximum width (or diameter) W1 of the through-electrode holes Hv of the first back-side metal plate layer 41 and the maximum width (or diameter) W2 of the back-side bump structures 50 may be substantially the same.

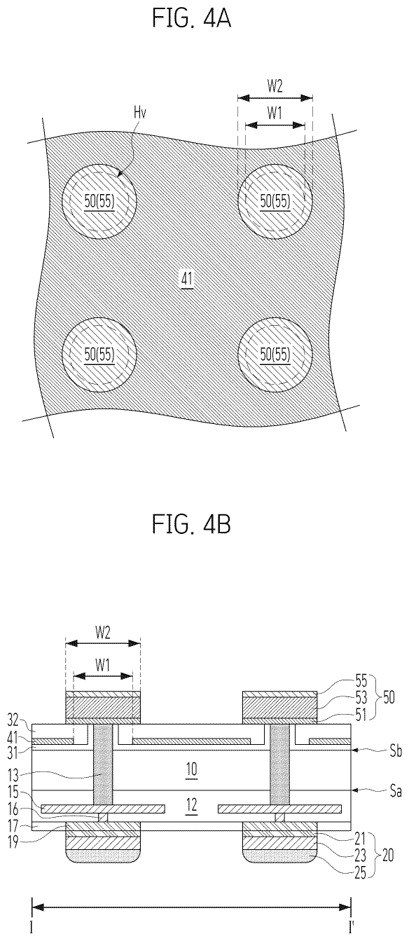

Referring to FIGS. 4A and 4B, the first back-side metal plate layer 41 and the back-side bump structures 50 may be partially vertically overlapped with each other. For example, in a vertical direction, portions of the first back-side metal plate layer 41 may be located between the back-side insulating layer 31 and the back-side bump structures 50. For example, the maximum width (or diameter) W1 of the through-electrode holes Hv of the first back-side metal plate layer 41 may be less than the maximum width (or diameter) W2 of the back-side bump structures 50. In FIG. 4A, the side surfaces of the first back-side metal plate layer 41 are indicated by dotted lines. When a decoupling effect or a shielding effect occurs between the through-electrodes 13 and the back-side bump structures 50, and the first back-side metal plate layer 41, the present embodiment can be applied.

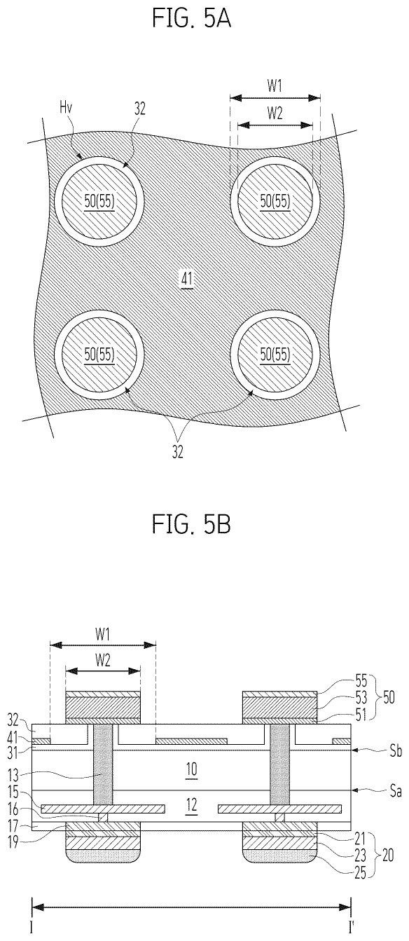

Referring to FIGS. 5A and 5B, the first back-side metal plate layer 41 and the back-side bump structures 50 might not be overlapped with each other in the vertical direction. For example, the maximum width (or diameter) W1 of the through-electrode holes Hv of the first back-side metal plate layer 41 may be greater than the maximum width (or diameter) W2 of the back-side bump structures 50. In a top view, the back-side passivation layer 32 may be exposed between the sides of the first back-side metal plate layer 41 and the sides of the back-side bump structures 50. When signal interferences occur between the through-electrodes 13 and the back-side bump structures 50 and the first back-side metal plate layer 41, the present embodiment can be applied.

In FIGS. 3A and 3B to 5A and 5B, the first back-side metal plate layer 41 can be replaced with the second back-side metal plate layer 42. That is, the first back-side metal plate layer 41 may include the second back-side metal plate layer 42. Accordingly, a process for manufacturing a semiconductor device can be simplified.

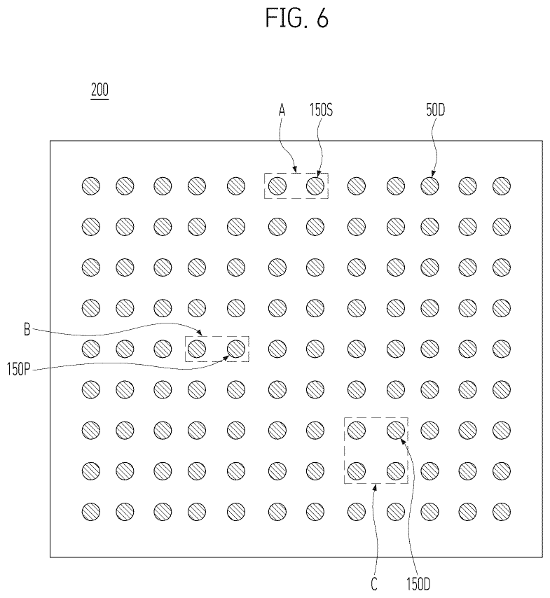

FIG. 6 is a schematic top view of a back-side surface of a semiconductor die 200 according to an embodiment of the present disclosure. Referring to FIG. 6, signal back-side bump structures 150S, power back-side bump structures 150P, and dummy back-side bump structures 150D may be disposed at arbitrary positions in a grid shape on a back-side surface of the semiconductor die 200.

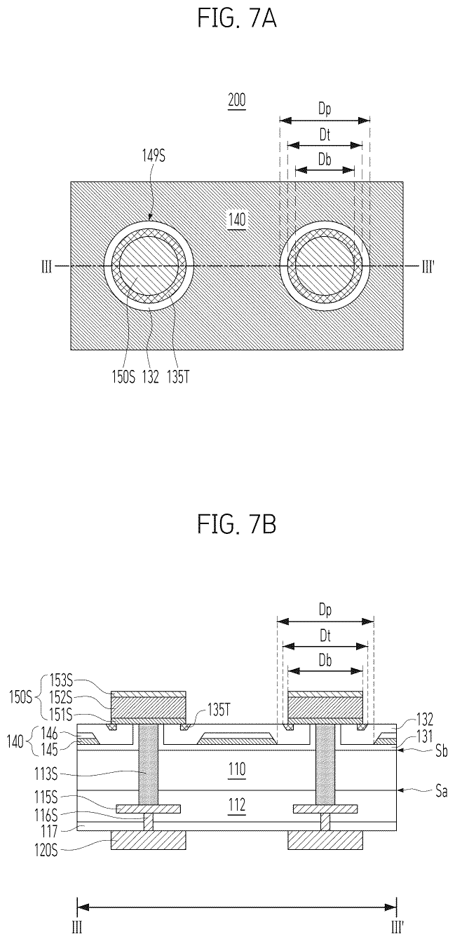

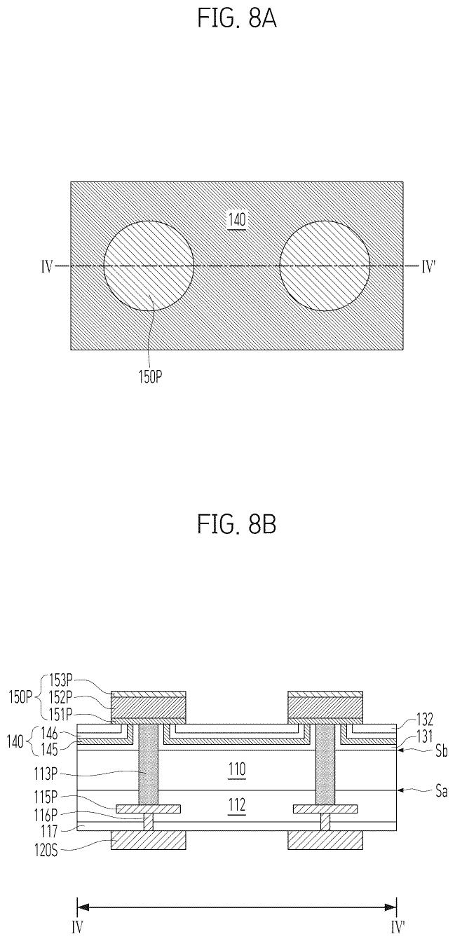

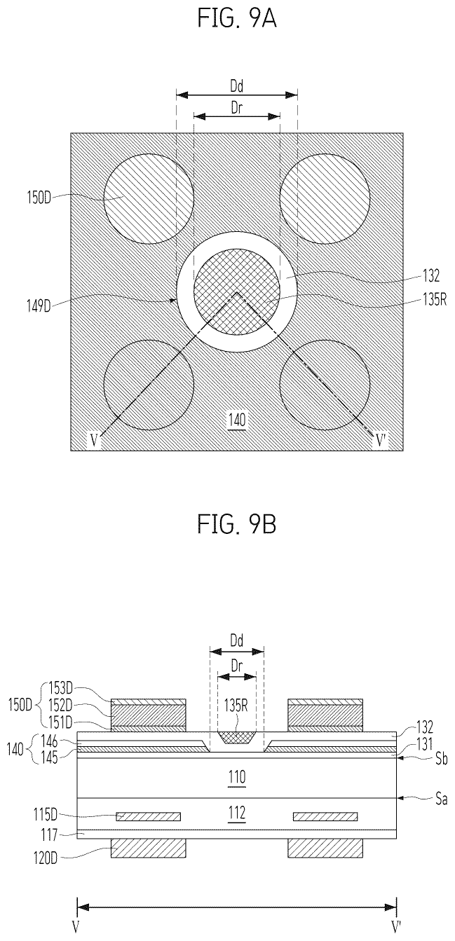

FIG. 7A is an enlarged top view of an area A of FIG. 6, and FIG. 7B is a longitudinal cross-sectional view taken along the line III-III′ of FIG. 7A. FIG. 8A is an enlarged top view of an area B of FIG. 6, and FIG. 8B is a longitudinal cross-sectional view taken along the line IV-IV′ of FIG. 8A. FIG. 9A is an enlarged top view of an area C of FIG. 6, and FIG. 9B is a longitudinal cross-sectional view taken along the line V-V′ of FIG. 9A. For example, the area A may be a signal bump area, the area B may be a power bump area, and the area C may be a dummy bump area.

Referring to FIGS. 7A, 7B, 8A, 8B, 9A, and 9B, a semiconductor die 200 according to an embodiment of the present disclosure may include a substrate 110, through-electrodes 113S and 113P, front-side bump structures 120S, 120P and 120D, a back-side metal plate layer 140, and back-side bump structures 150S, 150P and 150D. The semiconductor die 200 may further include an interlayer insulating layer 112, horizontal metal interconnections 115S, 115P, and 115D, vertical via plugs 116S and 116P, and a front-side passivation layer 117 on a front-side surface Sa (for example, an active surface) of the substrate 110. The semiconductor die 200 may further include a back-side insulating layer 131, a back-side passivation layer 132, and filling patterns 135T and 135R on a back-side surface Sb (for example, an inactive surface) of the substrate 110.

The substrate 110 may include a silicon wafer. Active circuit elements such as transistors may be disposed on the front-side surface Sa of the substrate 10. In the drawing, the front-side surface Sa of the substrate 10 may face downward, and the back-side surface Sb of the substrate 10 may face upward.

The through-electrodes 113S and 113P may vertically pass through the substrate 110. The through-electrodes 113S and 113P may include signal through-electrodes 113S and power through-electrodes 113P. For example, signal through-electrodes 113S may transfer various electrical signals such as data signals, command signals, address signals, clock signals, or strobe signals. The power through-electrodes 113P may selectively transfer various powers such as VDD, VCC, VDDi, VDDiQ, Vref, VPP_EXT, or VSS. Upper ends of the through-electrodes 113S and 113P may protrude from the back-side surface Sb of the substrate 110. Lower ends of the through-electrodes 113S and 113P may be positioned in the interlayer insulating layer 112.

The interlayer insulating layer 112 may be disposed on the front-side surface Sa of the substrate 110. The interlayer insulating layer 112 may cover the active circuit elements such as the transistors disposed on the front-side surface Sa of the substrate 110. The interlayer insulating layer 112 may include silicon oxide-based multilayer insulating layers.

The horizontal metal interconnections 115S, 115P and 115D may be surrounded by the interlayer insulating layer 112 and connected to the through-electrodes 113S and 113P. The horizontal metal interconnections 115S, 115P, and 115D may include signal horizontal metal interconnections 115S, power horizontal metal interconnections 115P, and dummy horizontal metal interconnections 115D. The signal horizontal metal interconnections 115S may be electrically connected to the signal through-electrodes 113S. For example, the signal horizontal metal interconnections 115S may be in physical contact with the lower ends of the signal through-electrodes 113S. The power horizontal metal interconnections 115P may be electrically connected to the power through-electrodes 113P. For example, the power horizontal metal interconnections 115P may be in physical contact with the lower ends of the power through-electrodes 113P. The dummy horizontal metal interconnections 115D may be electrically connected to one of the signal horizontal metal interconnections 115S or the power horizontal metal interconnections 115P, respectively. In an embodiment, the dummy horizontal metal interconnections 115D may be electrically floated.

The front-side passivation layer 117 may be disposed under the interlayer insulating layer 112. The front-side passivation layer 117 may include an insulating material such as silicon oxide or silicon nitride.

The vertical via plugs 116S and 116P may pass through the interlayer insulating layer 112 and the front-side passivation layer 117 to electrically connect the horizontal metal interconnections 115S, 115P and 115D to the front-side bump structures 120S, 120P and 120D. The vertical via plugs 116S and 116P may include signal vertical via plugs 116S electrically connecting the signal horizontal metal interconnections 115S to the signal front-side bump structures 120S, and power vertical via plugs 116P electrically connecting the power horizontal metal interconnections 115P to the power front-side bump structures 120P.

The front-side bump structures 120S, 120P, and 120D may be disposed under the front-side passivation layer 117. The front-side bump structures 120S, 120P, and 120D may include signal front-side bump structures 120S, power front-side bump structures 120P, and dummy front-side bump structures 120D. The signal front-side bump structures 120S may be electrically connected to the signal vertical via plugs 116S, and the power front-side bump structures 120P may be electrically connected to the power vertical via plugs 116P.

The back-side insulating layer 131 may be conformally disposed on the back-side surface Sb of the substrate 110. The back-side insulating layer 131 may conformally surround side surfaces of the upper ends of the through-electrodes 113S and 113P protruding from the back-side surface Sb of the substrate 110. The back-side insulating layer 131 may include a silicon nitride layer.

The back-side metal plate layer 140 may be disposed on the back-side insulating layer 131 in a plate shape. The back-side metal plate layer 140 may include a lower back-side metal plate layer 145 and an upper back-side metal plate layer 146. Side surfaces of the back-side metal plate layer 140 may be inclined.

The back-side passivation layer 132 may be disposed on the back-side insulating layer 131 to cover the back-side metal plate layer 140. The back-side passivation layer 132 may include a silicon nitride-based insulating material. When the back-side insulating layer 131 and the back-side passivation layer 132 include the same material, an interface between the back-side insulating layer 131 and the back-side passivation layer 132 may disappear.

The back-side bump structures 150S, 150P, and 150D may include signal back-side bump structures 150S, power back-side bump structures 150P, and dummy back-side bump structures 150D. The signal back-side bump structures 150S may be electrically connected to the signal through-electrodes 113S by vertically aligning and overlapped with the signal through-electrodes 113S. The power back-side bump structures 150P may be electrically connected to the power through-electrodes 113P by vertically aligning and overlapped with the power through-electrodes 113P. The dummy back-side bump structures 150D may be electrically floated. The signal back-side bump structures 150S may include signal back-side bump UBM layers 151S, signal back-side bump bodies 152S on the signal back-side bump UBM layers 151S, and a signal back-side bump capping layer 153S on the signal back-side bump bodies 152S. The power back-side bump structures 150P may include power back-side bump UBM layers 151P, power back-side bump bodies 152P on the power back-side bump UBM layers 151P, and a power back-side bump capping layer 153P on the power back-side bump bodies 152P. The dummy back-side bump structures 150D may include dummy back-side bump UBM layers 151D, dummy back-side bump bodies 152D on the dummy back-side bump UBM layers 151D, and a dummy back-side bump capping layer 153D on the dummy back-side bump bodies 152D. Each of the signal back-side bump UBM layers 151S, the power back-side bump UBM layers 151P, and the dummy back-side bump UBM layers 151D may include a titanium layer and a copper layer. For example, each of the signal back-side bump UBM layers 151S, the power back-side bump UBM layers 151P, and the dummy back-side bump UBM layers 151D may include a double layer. Each of the signal back-side bump bodies 152S, the power back-side bump bodies 152P, and the dummy back-side bump bodies 152D may include copper. Each of the signal back-side bump capping layers 153S, the power back-side bump capping layers 153P, and the dummy back-side bump capping layers 153D may include nickel or gold.

The filling patterns 135T and 135R may be damascened in the back-side passivation layer 132. The filling patterns 135T and 135R may include trench filling patterns 135T and a recess filling pattern 135R. In a top view, each of the trench filling patterns 135T may have a ring shape surrounding the signal back-side bump structures 150S and the signal through-electrodes 113S. In a longitudinal cross-sectional view, side surfaces of the signal back-side bump structures 150S may be vertically aligned or overlapped with the trench filling patterns 135T. In the top view, the trench filling patterns 135T may be partially vertically overlapped with the signal back-side bump structures 150S. The recess filling patterns 135R may be disposed between the dummy back-side bump structures 150D. Each of the trench filling patterns 135T and the recess filling pattern 135R may include an insulating material based on a silicon oxide.

Referring to FIGS. 7A and 7B, the back-side metal plate layer 140 may be spaced apart from the signal back-side bump structures 150S so as not to be vertically overlapped with the signal back-side bump structures 150S. The back-side metal plate layer 140 may not be electrically and physically connected to the signal back-side bump structures 150S. In the top view, the back-side metal plate layer 140 may have bump holes 149S surrounding the signal back-side bump structures 150S and the trench filling patterns 135T and exposing the back-side passivation layer 132. For example, the bump holes 149S may be vertically overlapped with the back-side signal bump structure 150S and the trench filling patterns 135T. In the top view, the exposed back-side insulating layer 132 may have a ring shape surrounding the trench filling patterns 135T. A maximum diameter Dp of each of the bump holes 149S of the back-side metal plate layer 140 may be greater than a maximum diameter Db of each of the signal back-side bump structures 150. The maximum diameter Dp of each of the bump holes 149S of the back-side metal plate layer 140 may be greater than a maximum diameter Dt of each of the trench filling patterns 135T. The maximum diameter Dt of each of the trench filling patterns 135T may be greater than the maximum diameter Db of each of the signal back-side bump structures 150S. The signal through-electrodes 113S, the signal back-side bump structures 150S, the trench filling patterns 135T, and the bump holes 149S may have a concentric circles shape.

Referring to FIGS. 8A and 8B, the back-side metal plate layer 140 may be vertically overlapped with outer portions of the power back-side bump structures 150P. The back-side metal plate layer 140 may conformally surround side surfaces of the upper ends of the power through-electrodes 113P. For example, the back-side metal plate layer 140 may surround the side surfaces of the back-side insulating layer 131 surrounding the side surfaces of the upper ends of the power through-electrodes 113P. The back-side metal plate layer 140 may be electrically and physically connected to lower surfaces of the power back-side bump structures 150P. For example, the back-side metal plate layer 140 may be electrically and physically connected to the power back-side bump UBM layers 151P.

Referring to FIGS. 9A and 9B, the back-side metal plate layer 140 may be vertically overlapped with the dummy back-side bump structures 150D. The back-side metal plate layer 140 may have a dummy hole 149D between the dummy back-side bump structures 150D. In the top view, the recess filling pattern 135R may be vertically overlapped with the dummy hole 149D. The dummy hole 149D may surround the recess filling pattern 135R. The dummy hole 149D and the recess filling pattern 135R may have a concentric circles shape.

Referring to FIG. 9A, in the top view, the recess filling pattern 135R may have a circular shape. In another embodiment, the recess filling pattern 135R may have a polygonal shape. The dummy hole 149D may expose the back-side insulating layer 131 and the recess filling pattern 135R. The exposed back-side insulating layer 131 may have a ring shape surrounding the recess filling pattern 135R. In another embodiment, the exposed back-side insulating layer 131 may have a polygonal shape surrounding the recess filling pattern 135R. The recess filling pattern 135R and the dummy hole 149D may have a concentric circles shape.

The signal back-side bump structures 150S, the signal through-electrodes 113S, the signal horizontal metal interconnections 115S, the signal vertical via plugs 116S, and the signal front-side bump structures 120S may be vertically aligned and electrically connected with each other. The power back-side bump structures 150P, the power through-electrodes 113P, the power horizontal metal interconnections 115P, the power vertical via plugs 116P, and the power front-side bump structures 120P may be vertically aligned and electrically connected with each other. The dummy back-side bump structures 150D, the dummy horizontal metal interconnections 115D, and the dummy front-side bump structures 120D may be vertically aligned with each other and may not be electrically connected with each other.

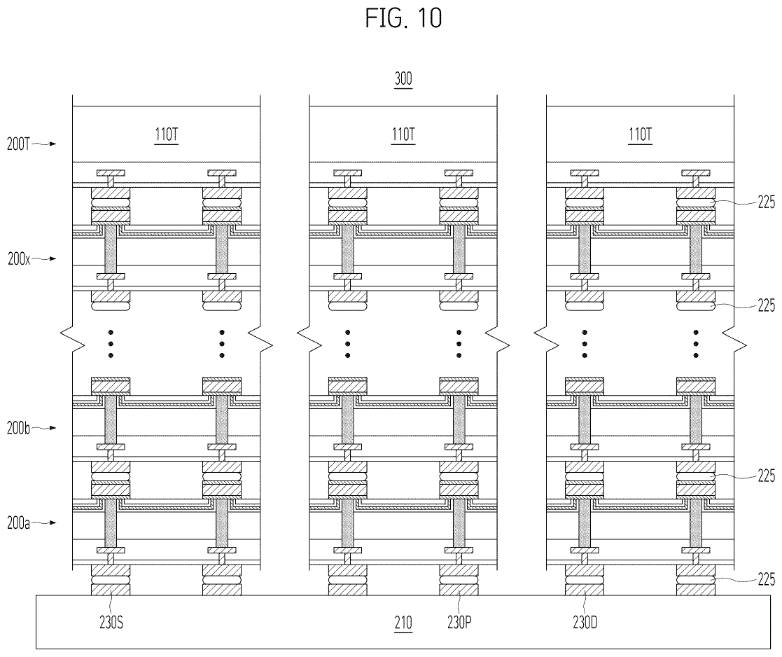

FIG. 10 is a longitudinal cross-sectional view schematically illustrating a semiconductor die stack structure 300 according to an embodiment of the present disclosure. For example, the semiconductor die stack structure 300 may be a high bandwidth memory (HBM) structure. Referring to FIG. 10, a semiconductor die stack structure 300 may include a plurality of semiconductor dies 200a-200x and 200T stacked on an interposer 210. Referring to FIGS. 7A and 7B to 9A and 9B, the signal front-side bump structures 120S and the signal back-side bump structures 150S of the semiconductor dies 200a-200x and 200T may be bonded through solders 225, the power front-side bump structures 120P and the power back-side bump structures 150P of the semiconductor dies 200a-200x and 200T may be bonded through the solders 225, and the dummy front-side bump structures 120D and the dummy back-side bump structures 150D of the semiconductor dies 200a-200x and 200T may be bonded through the solders 225. The front-side bump structures 120S, 120P, and 120D of the lowermost semiconductor die 200a may be bonded to solder lands 230S, 230P, and 230D of the interposer 210 through the solders 225, respectively. The solder lands 230S, 230P, and 230D may include signal solder lands 230S, power solder lands 230P, and dummy solder lands 230D. The semiconductor die 200T stacked on an uppermost part may not include the through-electrodes 113S and 113P. The bump structures 120S, 120P, 120D, 150S, 150P, and 150D and the solder 225 may be surrounded by an underfill material or a molding material. (not shown) he semiconductor die stack structure 300 may further include a molding member (not shown) covering the semiconductor dies 200a, 200b, 200c, 200x, and 200T.

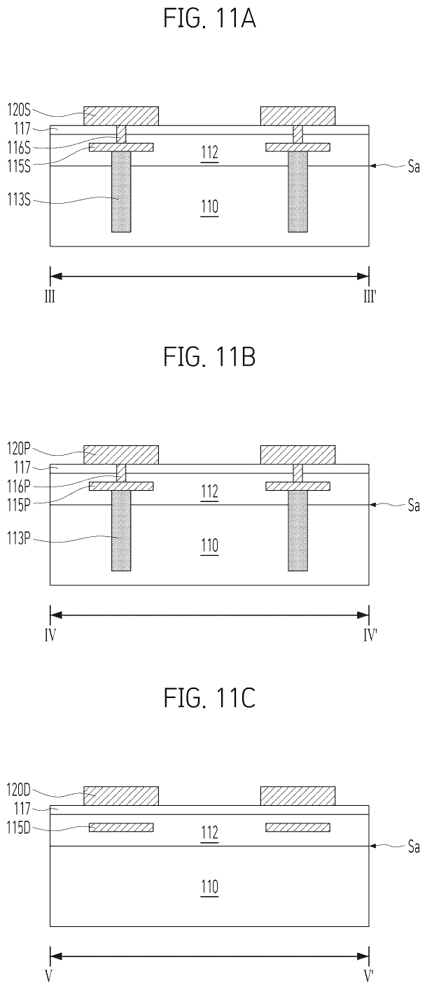

FIGS. 11A, 11B, and 11C to 18A, 18B, and 18C are longitudinal cross-sectional views illustrating a method of manufacturing a semiconductor die according to an embodiment of the present disclosure. FIGS. 11A to 18A are longitudinal cross-sectional views taken along the line III-III′ of FIG. 7A, FIGS. 11B to 18B are longitudinal cross-sectional views taken along the line IV-IV′ of FIG. 8A, and FIGS. 11C to 18C are longitudinal cross-sectional views taken along the line V-V′ of FIG. 9A.

Referring to FIGS. 11A, 11B, and 11C, a method of manufacturing a semiconductor die may include forming through-electrodes 113S and 113P in a substrate 110, forming an interlayer insulating layer 112, through-electrode connection interconnections 115S, 115P, and 115D, via plugs 116S and 116P, a front-side passivation layer 117, and front-side bump structures 120S, 120P and 120D on a front-side surface Sa, i.e., an active surface, of the substrate 110.

The substrate 110 may include a semiconductor layer such as a silicon wafer, a silicon germanium wafer, an epitaxially grown silicon layer or a silicon germanium layer, or a silicon on insulator (SOI). In the embodiment, the substrate 110 may be a silicon wafer.

Forming the interlayer insulating layer 112 may include performing a deposition process to form electrical elements such as transistors (not shown) on the front-side surface Sa (the active surface) of the substrate 110, and forming a silicon oxide-based insulating layer and/or a silicon nitride-based insulating layer on the front-side surface Sa to cover the electrical elements.

The through-electrodes 113S and 113P may include signal through-electrodes 113S and power through-electrodes 113P. Forming the through-electrodes 113S and 113P may include performing an etching process and a filling process to form conductive pillars partially penetrating the substrate 110. The filling process may include a plating process. First ends, for example, lower ends of the through-electrodes 113S and 113P may be positioned inside the substrate 110. Second ends, for example, upper ends of the through-electrodes 113S and 113P, may be positioned in the interlayer insulating layer 112 to be electrically connected the to through-electrode connection interconnections 115S and 115P, respectively.

The through-electrode connection interconnections 115S and 115P may include signal through-electrode connection interconnections 115S and power through-electrode connection interconnections 115P. Forming the through-electrode connection interconnections 115S and 115P may include performing a deposition process and an etching process to form metal interconnection patterns in the interlayer insulating layer 112 to be in contact with the second ends of the through-electrodes 113S and 113P. The through-electrode connection interconnections 115S and 115P may include a metal such as tungsten.

Forming the front-side passivation layer 117 may include performing a deposition process to form a silicon nitride-based or silicon oxide-based insulating layer on the interlayer insulating layer 112.

The via plugs 116S and 116P may include signal via plugs 116S and power via plugs 116P. Forming the via plugs 116S and 116P may include performing a via plug forming process to vertically penetrate a part of the interlayer insulating layer 112 and a part of the front-side passivation layer 117 to form metal pillars connected to the through-electrode connection interconnections 115S and 115P, respectively. The via plugs 116S and 116P may include a metal such as tungsten or copper.

The front-side bump structures 120S, 120P, and 120D may include signal front-side bump structures 120S, power front-side bump structures 120P, and dummy front-side bump structures 120D. Forming the front-side bump structures 120S, 120P, and 120D may include performing a plating process to form metal pad structures on the front-side passivation layer 117. The front-side bump structures 120S, 120P, and 120D may include one or a combination of metals such as titanium, nickel, tin, copper, palladium, lead, indium, bismuth, zinc, or gold. The signal front-side bump structures 120S may be electrically connected to the signal via plugs 116S, respectively, and the power front-side bump structures 120P may be electrically connected to the power via plugs 116S, respectively. The dummy front-side bump structures 120D may be formed on the front-side passivation layer 117 without electrical connections. In an embodiment, the dummy front-side bump structures 120D may be electrically connected to at least one of the power front-side bump structures 120P. For example, the dummy front-side bump structures 120D may be electrically connected to a ground voltage node. Referring to FIGS. 2A to 2E, the front-side bump structures 120S, 120P, and 120D may include front-side UBM layers, front-side bump bodies, and solder, respectively.

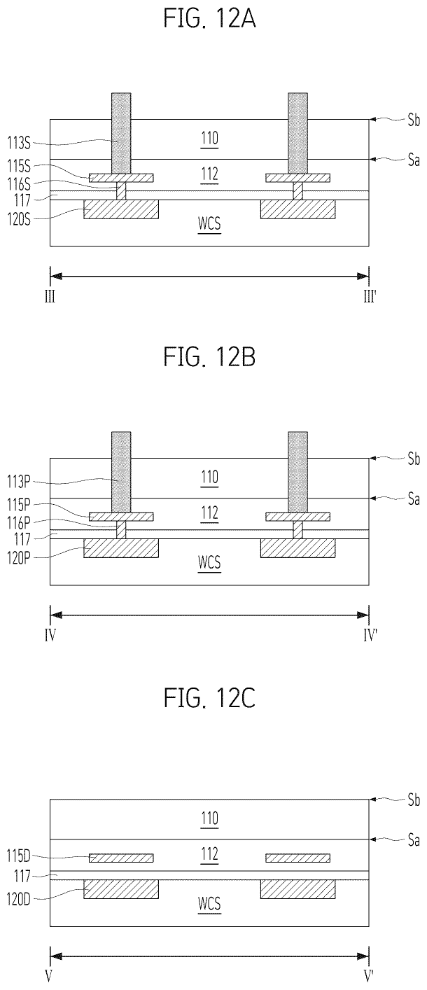

Referring to FIGS. 12A, 12B, and 12C, the method may further include inverting the substrate 110 and placing the substrate 110 on a wafer carrier substrate WSC, and performing a recess process to recess the back-side surface Sb, i.e., an inactive surface of the substrate 110. Upper ends of the signal through-electrode 113S and the power through-electrode 113P may be exposed to protrude from the recessed back-side surface Sb of the substrate 110. The recess process may include an etching process, for example, a dry etching process.

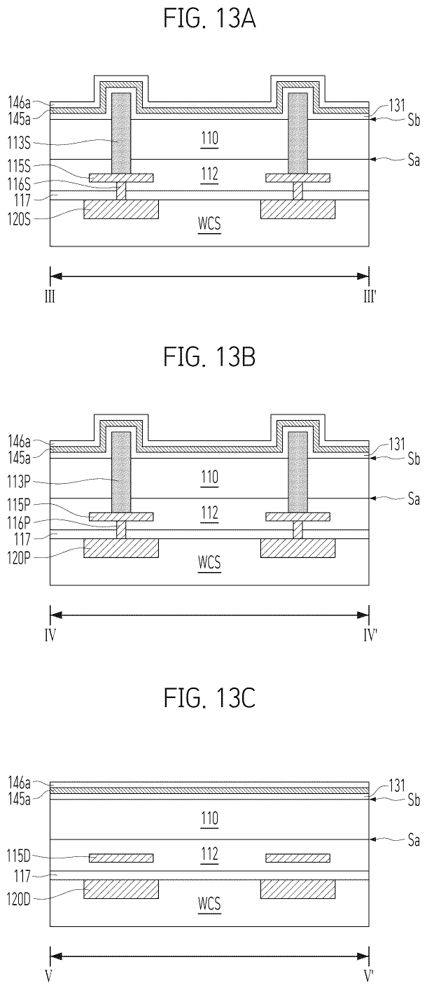

Referring to FIGS. 13A, 13B, and 13C, the method may further include forming a back-side insulating layer 131 conformally on the recessed back-side surface Sb of the substrate 110 and the surfaces of the exposed through-electrodes 113S and 113P, forming a lower back-side metal layer 145a conformally on the back-side insulating layer 131, and forming an upper back-side metal layer 146a on the lower back-side metal layer 145a. The back-side insulating layer 131 may be formed by performing a deposition process. The back-side insulating layer 131 may include a silicon nitride layer. The lower back-side metal layer 145a and the upper back-side metal layer 146a may be formed by performing a PVD process such as sputtering. In an embodiment, the upper back-side metal layer 146a may be formed by performing a plating process. In another embodiment, the upper back-side metal layer 146a may be formed by sequentially performing a PVD process and a plating process. The lower back-side metal layer 145a may include titanium. The upper back-side metal layer 146a may include copper. The lower back-side metal layer 145a may increase adhesion between the back-side insulating layer 131 and the upper back-side metal layer 146a. The upper back-side metal layer 146a may be sufficiently thicker than the lower back-side metal layer 145a.

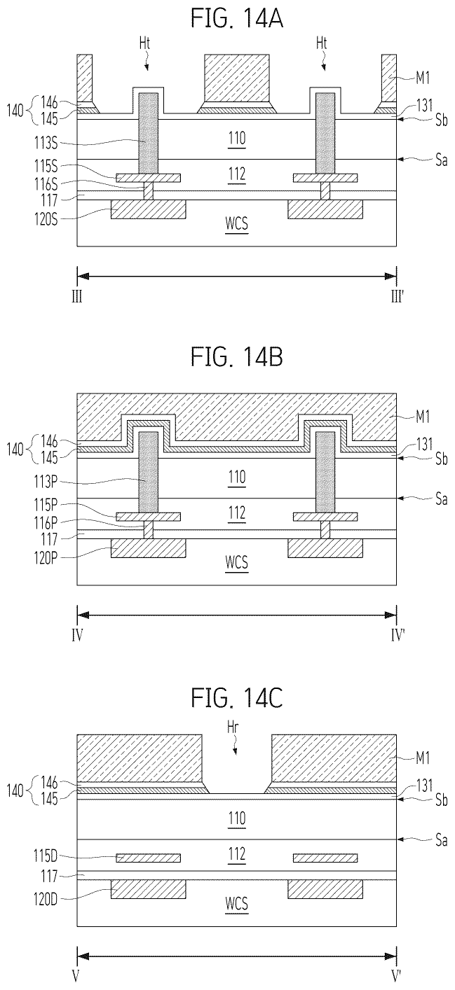

Referring to FIGS. 14A, 14B, and 14C, the method may further include forming a first mask pattern M1 having trench holes Ht exposing surroundings of the protruding upper ends of the signal through-electrodes 113S and a recess hole Hr vertically aligned with a space between the dummy front-side bump structures 120D, and removing the lower back-side metal layer 145a and the upper back-side metal layer 146a exposed in the trench holes Ht and the recess hole Hr. The back-side insulating layer 131 may be exposed in the trench holes Ht and the recess hole Hr. The first mask pattern M1 may include a photoresist. The lower back-side metal layer 145a and the upper back-side metal layer 146a may be patterned to be a lower back-side metal plate layer 145 and an upper back-side metal plate layer 146. The lower back-side metal plate layer 145 and the upper back-side metal plate layer 146 may form a back-side metal plate layer 140. Side surfaces of the back-side metal plate layer 140 exposed in the first hole H1 and the second hole H2 may be inclined. For example, side ends of the lower back-side metal plate layer 145 may protrude from the side end of the upper back-side metal plate layer 146 in a lateral direction.

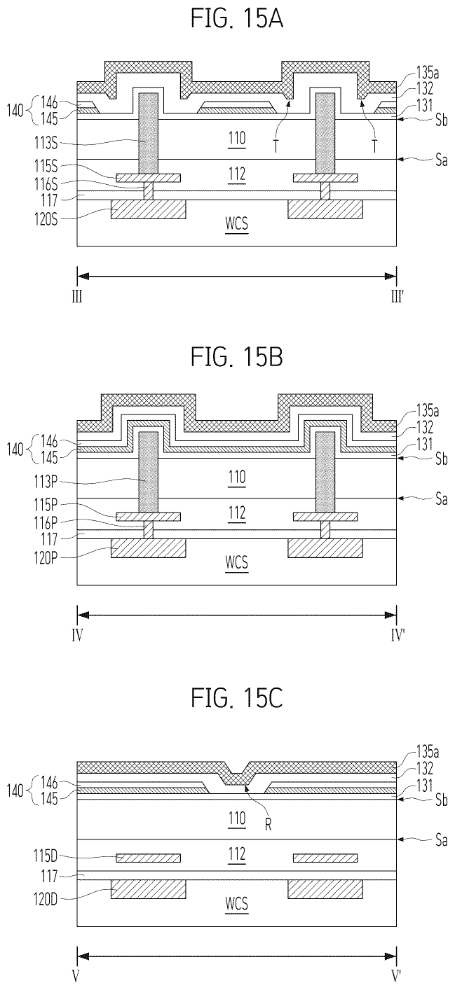

Referring to FIGS. 15A, 15B, and 15C, the method may further include removing the first mask pattern M1, conformally forming a back-side passivation layer 132, and conformally forming a filling insulating layer 135a on the back-side passivation layer 132. The back-side passivation layer 132 may include a recess R vertically aligned with a space between the trenches T around the signal through-electrodes 113S and the dummy front-side bump structures 120D. The filling insulating layer 135a may completely fill the trenches T and may partially fill the recess R.

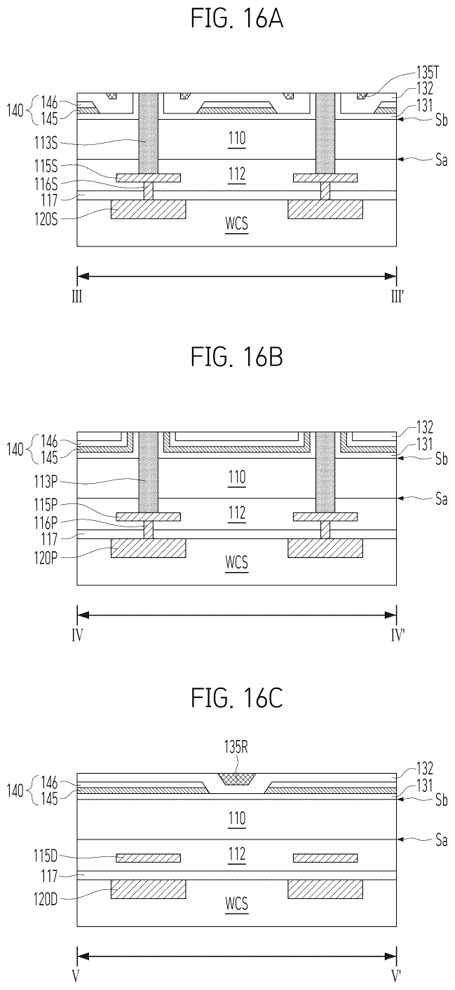

Referring to FIGS. 16A, 16B, and 16C, the method may further include performing a planarization process to expose a top surfaces of the through-electrodes 113S and 113P. The planarization process may include a chemical mechanical polishing (CMP) process. The filling insulating layer 135a may be formed to a trench filling pattern 135T confined in the trench T and a recess filling pattern 135R confined in the recess R. Referring to FIG. 7A, the trench filling pattern 135T may have a ring shape surrounding the signal through-electrode 113S and the signal back-side bump structure 150S. Referring to FIG. 9A, the recess filling pattern 135R may be positioned between the dummy back-side bump structures 150D to have a circular shape or a polygonal shape. Top surfaces or upper ends of the through-electrodes 113S and 113P, the back-side insulating layer 131, the lower back-side metal plate layer 145, the upper back-side metal plate layer 146, the back-side passivation layer 132, the trench filling patterns 135T, and the recess filling pattern 135R may be coplanar.

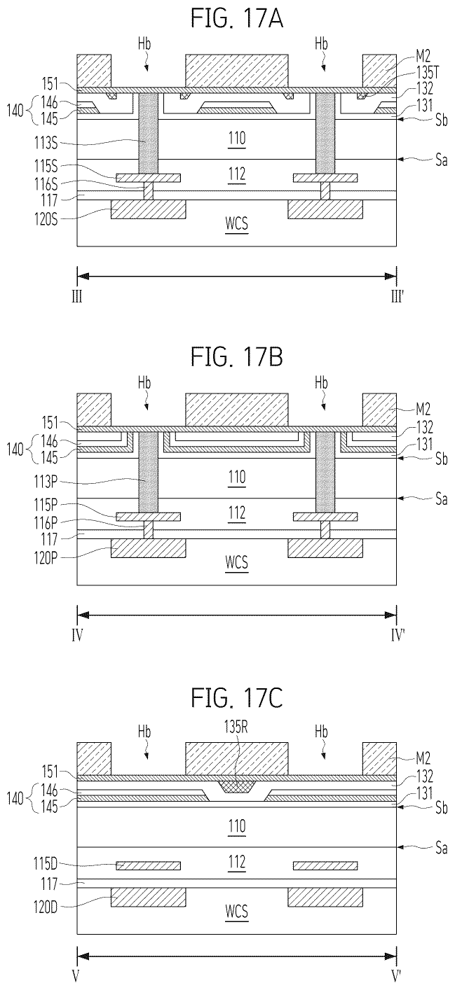

Referring to FIGS. 17A, 17B, and 17C, the method may include entirely forming a back-side bump UBM layer 151 and forming a second mask pattern M2. The back-side bump UBM layer 151 may be conformally formed on the top surfaces or the upper portions of the through-electrodes 113S and 113P, the back-side insulating layer 131, the lower back-side metal plate layer 145, the upper back-side metal plate layer 146, the back-side passivation layer 132, the trench filling patterns 135T, and the recess filling pattern 135R. The back-side bump UBM layer 151 may be formed by performing a PVD process. The back-side bump UBM layer 151 may include a titanium layer and a copper layer. The second mask pattern M2 may have back-side bump holes Hb vertically aligned with the back-side through-electrodes 113S and 113P or the front-side bump structures 120S, 120P and 120D, respectively.

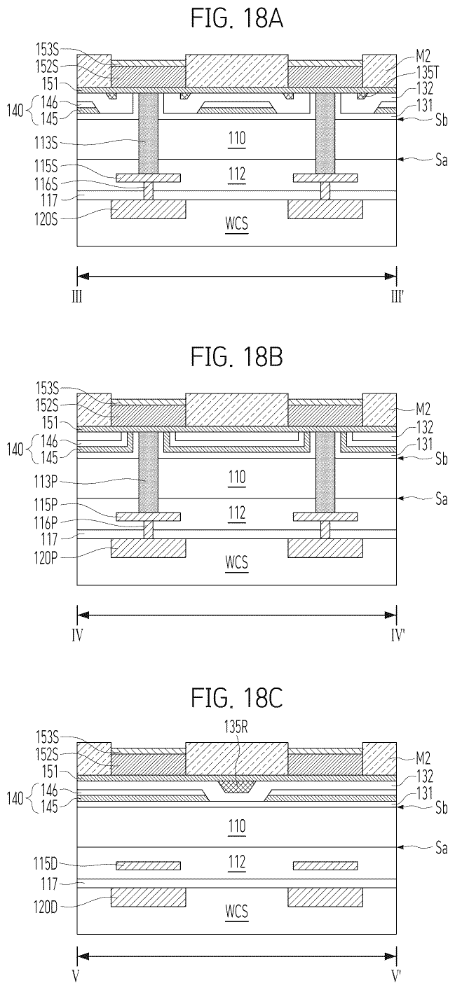

Referring to FIGS. 18A, 18B, and 18C, the method may further include performing a plating process to form back-side bump bodies 152S, 152P, and 152S on the back-side bump UBM layer 151 exposed in the back-side bump holes Hb, and forming back-side bump capping layers 153S, 153P, and 153D on the back-side bump bodies 152S, 152P, and 152D. The back-side bump bodies 152S, 152P, and 152D may include a signal back-side bump body 152S, a power back-side bump body 152P, and a dummy back-side bump body 152D. The back-side bump bodies 152S, 152P, and 152D may include copper. The back-side bump capping layers 153S, 153P, and 153D may include a signal back-side bump capping layer 153S, a power back-side bump capping layer 153P, and a dummy back-side bump capping layer 153D. The back-side bump capping layers 153S, 153P, and 153D may include nickel or gold.

Thereafter, referring to FIGS. 7B, 8B, and 9B, the method may include removing the second mask pattern M2 to expose a portion of the back-side bump UBM layer 150, and to remove the exposed back-side bump UBM layer. The back-side bump UBM layer 151 may be separated and formed into a signal back-side bump UBM layer 151S, a power back-side bump UBM layer 151P, and a dummy back-side bump UBM layer 151D. The signal back-side bump UBM layer 151S, the signal back-side bump body 152S, and the signal back-side bump capping layer 153S may form the signal back-side bump structure 150S. The power back-side bump UBM layer 151P, the power back-side bump body 152P, and the power back-side bump capping layer 153P may form the power back-side bump structure 150P. The dummy back-side bump UBM layer 151D, the dummy back-side bump body 152D, and the dummy back-side bump capping layer 153D may form the dummy back-side bump structure 150D.

According to the embodiments of the present disclosure, a warpage occurring in the semiconductor die manufacturing process may be prevented and reduced.

While the present invention has been described with respect to the specific embodiments, it will be apparent to those skilled in the art that various changes and modifications may be made without departing from the spirit and scope of the invention as defined in the following claims.

What is claimed is:

1. A semiconductor die comprising:
interlayer insulating layer over a front-side of a substrate;
a signal horizontal metal interconnection and a power horizontal metal interconnection in the interlayer insulating layer;
a front-side passivation layer over the interlayer insulating layer;
a signal front-side bump structure and a power front-side bump structure over the front-side passivation layer;
a signal vertical via plug passing through the front-side passivation layer to electrically connect the signal horizontal metal interconnection to the signal front-side bump structure;
a power vertical via plug passing through the front-side passivation layer to electrically connect the power horizontal metal interconnection to the power front-side bump structure;
a back-side insulating layer over a back-side of the substrate;
a back-side metal plate layer over the back-side insulating layer;
a back-side passivation layer covering the back-side metal plate layer;
a signal back-side bump structure and a power back-side bump structure over the back-side passivation layer;
a signal through-electrode passing through the substrate to electrically connect the signal horizontal metal interconnection to the signal back-side bump structure; and
a power through-electrode passing through the substrate to electrically connect the power horizontal metal interconnection to the power back-side bump structure,
wherein upper ends of the signal through-electrode and the power through-electrode protrude from the back-side surface of the substrate,
wherein the back-side metal plate layer is spaced apart from the signal through-electrode so as not to be electrically connected to the signal through-electrode, and
wherein the back-side metal plate layer is electrically connected to the power bump structure.

2. The semiconductor die of claim 1,
wherein the back-side insulating layer conformally surrounds side surfaces of the protruding upper ends of the signal through-electrode and the power through-electrode, and
wherein a part of the back-side metal plate layer conformally surrounds side surfaces of the back-side insulating layer surrounding the side surfaces of the protruding upper ends of the power through-electrode.

3. The semiconductor die of claim 2,
wherein the part of the back-side metal plate layer is electrically and physically connected to a lower surface of the power back-side bump structure.

4. The semiconductor die of claim 1,
wherein the back-side metal plate layer has a bump hole through which the protruding upper end of the back-side through-electrode passes.

5. The semiconductor die of claim 4,
wherein the bump hole surrounds the power back-side bump structure, in a top view.

6. The semiconductor die of claim 5,
wherein a part of the back-side passivation layer is exposed in the bump hole to surround the power back-side bump structure, in the top view.

7. The semiconductor die of claim 5, further comprising:
a trench filling pattern damascened within the back-side passivation layer,
wherein the trench filling pattern has a ring shape, in the top view.

8. The semiconductor die of claim 7,
wherein the bump hole surrounds the trench filling pattern, and the trench filling pattern surrounds the back-side power bump structure, in the top view.

9. The semiconductor die of claim 7,
wherein an outer portion of the power back-side bump structure and the trench filling pattern is vertically overlapped.

10. The semiconductor die of claim 7,
wherein the back-side metal plate layer and the trench filling pattern are not vertically overlapped with each other.

11. The semiconductor die of claim 1, further comprising:
a dummy horizontal metal interconnection in the interlayer insulating layer;
a dummy front-side bump structure over the front-side passivation layer; and
a dummy back-side bump structure over the back-side passivation layer,
wherein the dummy horizontal metal interconnection, the dummy front-side bump structure, and the dummy back-side bump structure are not electrically connected to each other.

12. The semiconductor die of claim 11,
wherein the dummy horizontal metal interconnection, the dummy front-side bump structure, and the dummy back-side bump structure are vertically overlapped with each other.

13. The semiconductor die of claim 11,
wherein the back-side metal plate layer further includes a dummy hole not vertically overlapped with the dummy back-side bump structure.

14. The semiconductor die of claim 13, further comprising:
a recess filling pattern damascened within the back-side passivation layer,
wherein the recess filling pattern is vertically overlapped with the dummy hole.

15. The semiconductor die of claim 1,
wherein the signal horizontal metal interconnection, the signal front-side bump structure, the signal through-electrode, and the signal back-side bump structure are vertically overlapped with each other, and
wherein the power horizontal metal interconnection, the power front-side bump structure, the power through-electrode, and the power back-side bump structure are vertically overlapped with each other.

16. A semiconductor die comprising:
an interlayer insulating layer over a front-side of a substrate;
a first horizontal metal interconnection, a second horizontal metal interconnection, and a third horizontal metal interconnection in the interlayer insulating layer;
a front-side passivation layer over the interlayer insulating layer;
a first front-side bump structure, a second front-side bump structure, and a third front-side bump structure over the front-side passivation layer;
a first vertical via plug passing through the front-side passivation layer to electrically connect the first horizontal metal interconnection to the first front-side bump structure;
a second vertical via plug passing through the front-side passivation layer to electrically connect the second horizontal metal interconnection to the second front-side bump structure;
a back-side insulating layer over a back-side of the substrate;
a back-side metal plate layer over the back-side insulating layer;
a back-side passivation layer covering the back-side metal plate layer;
a first back-side bump structure, a second back-side bump structure, and a third back-side bump structure over the back-side passivation layer;
a first through-electrode passing through the substrate to electrically connect the first horizontal metal interconnection to the first back-side bump structure; and
a second through-electrode passing through the substrate to electrically connect the second horizontal metal interconnection to the second back-side bump structure,
wherein the back-side metal plate layer is spaced apart from the first back-side bump structure and the first through-electrode, respectively,
wherein the back-side metal plate layer is electrically and physically connected to the second back-side bump structure, and
wherein the back-side metal plate layer is vertically overlapped with the third back-side bump structure.

17. The semiconductor die of claim 16,
wherein the back-side metal plate layer includes a bump hole vertically overlapped with the first back-side bump structure, and
wherein the first through-electrode passes through the bump hole.

18. The semiconductor die of claim 16,
wherein one end of the second through-electrode protrudes from the back-side surface of the substrate,
wherein the back-side insulating layer surrounds a side surface of the protruding one end of the second through-electrode, and
wherein a part of the back-side metal plate layer surrounds a side surface of the back-side insulating layer surrounding a side surface of one end of the second through-electrode which protrudes.

19. The semiconductor die of claim 16, further comprising:
a fourth front-side bump structure over the front-side passivation layer; and
a fourth back-side bump structure over the back-side passivation layer,
wherein the back-side metal plate layer is vertically overlapped with the fourth back-side bump structure,
wherein the back-side metal plate layer includes a dummy hole between the third back-side bump structure and the fourth back-side bump structure,
wherein the back-side metal plate layer is not electrically and physically connected to the third back-side bump structure and the fourth back-side bump structure.

20. The semiconductor die of claim 16,
wherein the first horizontal metal interconnection, the first front-side bump structure, the first through-electrode, and the first back-side bump structure are vertically overlapped with each other,
wherein the second horizontal metal interconnection, the second front-side bump structure, the second through-electrode, and the second back-side bump structure are vertically overlapped with each other, and
wherein the third horizontal metal interconnection, the third front-side bump structure, and the third back-side bump structure are vertically overlapped with each other.
